(19) United States
(12) Patent Application Publication
(10) Pub. No.: US 2009/0303685 A1
(43) Pub. Date: Dec. 10, 2009

(54) Interface module with high heat-dissipation

(76) Inventor: H.W. Chen, Yilan City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/155,776

(22) Filed: Jun. 10, 2008

(51) Int. Cl. H05K 7/20

(52) U.S. Cl. 361/710

(57) ABSTRACT

This invention relates to an interface module with high heat dissipation, comprising a metal base, an electrical insulation layer with high heat-conductivity and a metal circuit. The electrical insulation layer with high heat-conductivity is provided on the heat absorption end surface of the metal base, and the metal circuit is formed on the electrical insulation layer with high heat-conductivity for the direct mounting of various electronic components such as chip or LED etc. thereon. In this manner, the function of conventional circuit board, heat sink paste and a part or the whole heat sink unit can be substituted by the interface module with high heat-dissipation such that the waste heat generated by electronic component can be transferred out directly through the interface module with high heat-dissipation so as to solve such problem concerned with heat dissipation as heat jamming in the package area.

### BACKGROUND OF THE INVENTION

1. Field of the Invention

This invention relates to an interface module with high heat-dissipation used to substitute conventional circuit board, heat sink paste and a part or the whole of heat sink unit, and a metal circuit can be formed directly and various electronic components such as chip or LED can be packaged on the surface thereof. Heat sink paste is not used between electronic components such that waste heat generated by electronic components during operation can be transferred out directly through the interface module with high heat-dissipation so as to achieve the goal of obtaining high heat-dissipation efficiency.

2. Brief Description of the Prior Art

Accompanying with perpetual increase of the power of chip, LED or various electronic components, the working waste heat thereof is relatively increased with respect to the raising of power proportionally. If the exhaust of waste heat is unable to be kept pace with the increase of waste heat amount, the temperature of the chip, LED or various electronic components will tend to increase. In turn, this will cause reduction on working efficiency and even the damage thereof. When reviewing the method of heat dissipation for conventional heat sink unit, heat pipe and fan, for example, the waste heat of electronic components such as chip, LED is transferred to heat sink unit through the contact with the heat sink paste and heat sink unit and is then exhausted to the outside by fan. In practical application, there are three major defects in the present method of heat dissipation listed as follow.
1. The chip, LED or various electronic components has polymer material structure with high heat-resistance for insulation package use, which causes heat jamming and heat accumulating problem of the package layer.
2. Electronic components are mounted on the substrate made of polymer material having high heat-resistance, which causes heat jamming of the circuit board.
3. When heat sink paste is applied between the structural layers, bubbles and structure defects exist in the heat sink paste interface so that heat jamming happens between the structure layers.

So far, the way of solving the above heat-resistance problem is mostly to increase the fin area of heat sink or to raise the rotation speed of fan so as to enhance the heat dissipation efficiency. However, this measure of increasing the efficiency in the heat sink terminal fails to contribute efficiently and reasonably to the improvement or solution with respect to the heat transfer efficiency between the heat source (i.e., the LED) and the heat dissipating terminal (i.e., the heat sink).

So far, there are several ways developed to solve the above heat dissipation problem listed as below.

Firstly, in Japanese Patent No. JP2004-200347, an electrically conductive mixture using diamond and metal material is disclosed as an electrically conductive heat-dissipating layer of lamination between the p-n diodes of the LED. However, this technology only improves the heat dissipation structure in the interior of the LED, thus does not provide any efficient solution with respect to the heat jamming in the insulation package layer with high heat-resistance outside the LED.

Secondly, in Japanese Patent No. JP-Heisei 5-347369, a constitution of small granular diamond mixing with epoxy resin or silicone resin is disclosed which is used as a heat-dissipating insulation package layer for electronic components. This technology improves heat dissipation problem of package layer on the upper portion of electronic components, but fails to solve defect problem of interface between the insulated circuit board with high heat-resistance and the heat sink paste. In addition, since this technology uses the constitution of small granular diamond mixing with epoxy resin, quartz granule or alumina granule as heat-dissipating insulation package layer for electronic components, the tensile stress feature of which is unable to meet the requirement of suppressing the damage caused by expansion and contraction caused by long-term temperature variation.

Thirdly, in PRC Patent No. CN15455148, a technology is disclosed in which LED with big power is adhered to the heat dissipating structure on the diamond substrate. This technology utilizes multi-layers heat sink paste between structure layers so as to achieve good heat transfer. However, in the case of practical application, heat resistance is raised in view of the increase of bubbles, impurities and material defect caused by the increase of interface. Therefore, this technology did not propose a total solution for heat transfer including the items of lowering heat-resistance channels, reducing the complexity of heat conduction structure and the number of interface, ensuring the interface bubbles of the heat sink paste.

### SUMMARY OF THE INVENTION

The main object of the present invention is to provide an interface module with high heat-dissipation so as to solve heat-resistance generated between the structure layers, moreover to exhaust concretely the waste heat generated by various electronic components such as chip, LED etc. during operation thereof.

In order to achieve above object, the interface module with high heat-dissipation of the present invention mainly comprises an electrical insulation layer with high heat-conductivity provided on a part or the whole of the heat absorption end surface of a metal base, and a metal circuit is formed on the electrical insulation layer with high heat-conductivity for the direct mounting of various electronic components such as chip or LED etc. thereon. In this manner, with the assistance of the design of the interface module having high heat-dissipation, various electronic components such as chip, LED etc. are no longer to be packaged on conventional circuit board having high heat-resistance feature any more. Simultaneously, with the help of high heat-conductivity of the electrical insulation layer with high heat-conductivity and without the application of heat sink paste between structure layers, waste heat generated by various electronic components such as chip or LED etc. can be transferred out promptly through the interface module with high heat-dissipation so as to solve such problem concerned with heat dissipation as heat jamming and heat accumulating in the package area.

Preferably, said metal base is at least one layer or more than one layer structure body without containing any insulation material.

Preferably, said metal base is a structure body with single layer, the material of which is selected from one of Cu or Al.

Preferably, said metal base comprises a first structure layer and a second structure layer, said first structure layer being one material selected from Cu or Al, while said second structure layer being one material selected from SiC, Si, Mo or Ti.

Preferably, the electrical insulation layer with high heat-conductivity is formed by lamination using a method selected from vapor deposition, sputtering, insert welding, stamping, injecting, screen printing, sintering and spray-coating. The material of the electrical insulation layer with high heat-conductivity is at least one material selected from diamond, aluminum nitride, SiC, diamond powder mixing with polymer material, diamond-like carbon or nano diamond.

Preferably, the heat emitting end surface of said metal base is provided with a micro-structure selected from micro-pit, micro-protrusion, porosity or sponge-like opening, and a heat radiation layer is formed on the micro-structure by lamination using a method selected from vapor deposition, sputtering, electroplating, sintering and spray-coating. The material of the heat radiation layer is at least one material selected from diamond, aluminum nitride, SiC, diamond-like carbon or nano diamond.

Preferably, a plurality of fins are provided on the heat emitting end of the metal base, and each fin is provided with a micro-structure selected from micro-pit, micro-protrusion, porosity or sponge-like opening, and a heat radiation layer is formed on the micro-structure by lamination using a method selected from vapor deposition, sputtering, electroplating, sintering and spray-coating. The material of the heat radiation layer is at least one material selected from diamond, aluminum nitride, SiC, diamond-like carbon or nano diamond.

Preferably, the heat emitting end of said metal base is combined with a heat sink unit.

Preferably, said heat sink unit is a heat pipe or a thermoelectric cooling chip.

Preferably, the heat emitting end of said metal base has a combination hole for the insertion and combination with heat pipe, and a plurality of fins are provided on the heat emitting end of the heat pipe.

Preferably, each fin is provided with a micro-structure selected from micro-pit, micro-protrusion, porosity or sponge-like opening, and a heat radiation layer is formed on the micro-structure by lamination using a method selected from vapor deposition, sputtering, electroplating, sintering and spray-coating. The material of the heat radiation layer is at least one material selected from diamond, aluminum nitride, SiC, diamond-like carbon or nano diamond.

### BRIEF DESCRIPTION OF ACCOMPANYING DRAWINGS

FIG. 1 is a schematic view of the structure of the first embodiment of the interface module with high heat-dissipation of the present invention.

FIG. 2 is a schematic view of the structure of the second embodiment of the interface module with high heat-dissipation of the present invention.

FIG. 3 is a partial enlarged view of the encircled portion A in FIG. 1.

FIG. 4 is a schematic view of the structure of the third embodiment of the interface module with high heat-dissipation of the present invention.

FIG. 5 is a partial enlarged view of the, encircled portion B in FIG. 4.

FIG. 6 is an exploded view showing the first combination mode of the interface module with high heat-dissipation and the heat sink unit.

FIG. 7 is an assembled view showing the first combination mode of the interface module with high heat-dissipation and the heat sink unit.

FIG. 8 is a partial enlarged view of the encircled portion C in FIG. 7.

FIG. 9 is an assembled view showing the second combination mode of the interface module with high heat-dissipation and the heat sink unit.

FIG. 10 is an assembled view showing the first combination mode of the interface module with high heat-dissipation and the heat sink unit.

FIG. 11 is a schematic view of the structure of the third embodiment of the interface module with high heat-dissipation of the present invention.

### DETAILED DESCRIPTION OF THE PREFERRED EMBODIMENTS

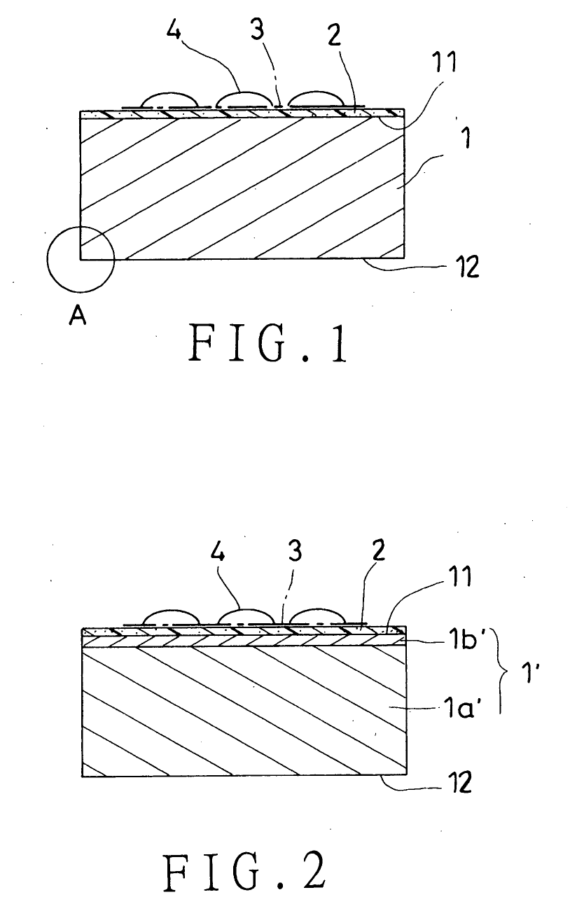

Referring to FIG. 1, the first preferred embodiment of the interface module with high heat-dissipation of the present invention is shown, comprising:

a metal base (1) in which the heat absorption end (11) is defined as the end face for mounting the electronic component (4), and the other end face opposite to the heat absorption end (11) is the heat emitting end (12). The metal base (1) is at least one or more than one structure layer without containing any insulation material. As shown in FIG. 1, the metal base (1) is a single layer structure body the material of which is one material selected from Cu and Al. The metal base (1′) shown in FIG. 2 is a double layer structure body containing a first structure layer (1a′) and a second structure layer (1b′). The first structure layer (1a′) is one material selected from Cu and Al, while the second structure layer (1b′) is one material selected from SiC, Si, Mo or Ti. Further, the multi-layer metal base (1′) is formed by co-rolling all the materials after lamination of each layer;

an electrical insulation layer (2) with high heat-conductivity formed on the heat absorption end (11) of the metal base (1) by lamination using a method selected from extrusion, insert welding, stamping, screen printing, spray-coating, remastering or vapor deposition, sputtering, injection, sintering. And the material of the electrical insulation layer with high heat-conductivity is at least one material selected from diamond, aluminum nitride, SiC, diamond powder mixing with polymer material, diamond-like carbon or nano diamond;

a metal circuit (3) formed on the electrical insulation layer (2) with high heat-conductivity.

According to the above structure design, the interface module with high heat-dissipation is thus formed.

Various electronic components (4) with heat generation such as chip or LED etc. are mounted and packaged on the metal circuit (3) of the interface module with high heat-dissipation.

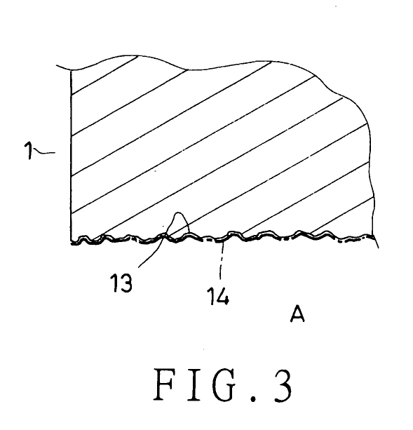

The surface of the heat emitting end (12) of the metal base (1) is provided with a micro-structure (13), as shown in FIG. 3, which can be one selected from the shape of micro-pit, micro-protrusion, porosity or sponge-like opening, and a heat radiation layer (14) is formed on the surface of the micro-structure (13) by vapor deposition, sputtering, electroplating, sintering or spray-coating. The material of the heat radiation layer (14) is at least one material selected from diamond, aluminum nitride, SiC, diamond-like carbon or nano diamond.

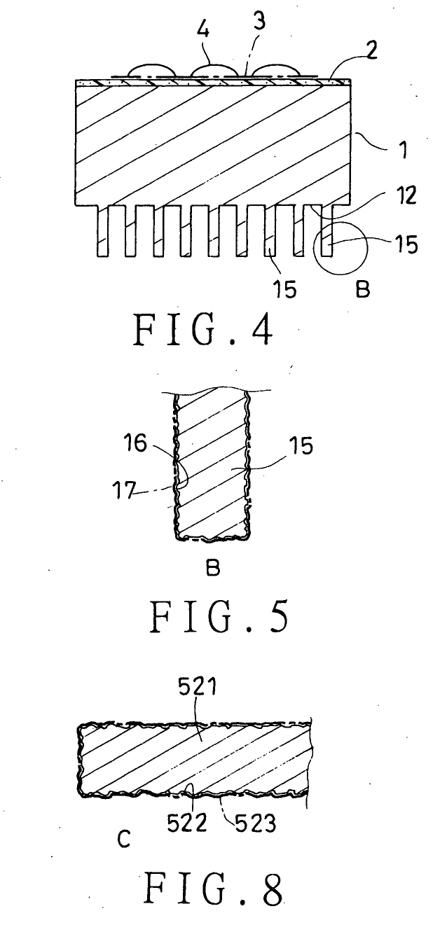

A plurality of fins (15) are provided on the surface of the heat emitting end (12) of the interface module with high heat-dissipation, as shown in FIG. 4. Preferably, each fin (15) is provided with a micro-structure (16), as shown in FIG. 5, which can be one selected from the shape of micro-pit, micro-protrusion, porosity or sponge-like opening, and a heat radiation layer (17) is formed on the surface of the micro-structure (16) by vapor deposition, sputtering, electroplating, sintering or spray-coating. The material of the heat radiation layer (17) is at least one material selected from diamond, aluminum nitride, SiC, diamond-like carbon or nano diamond.

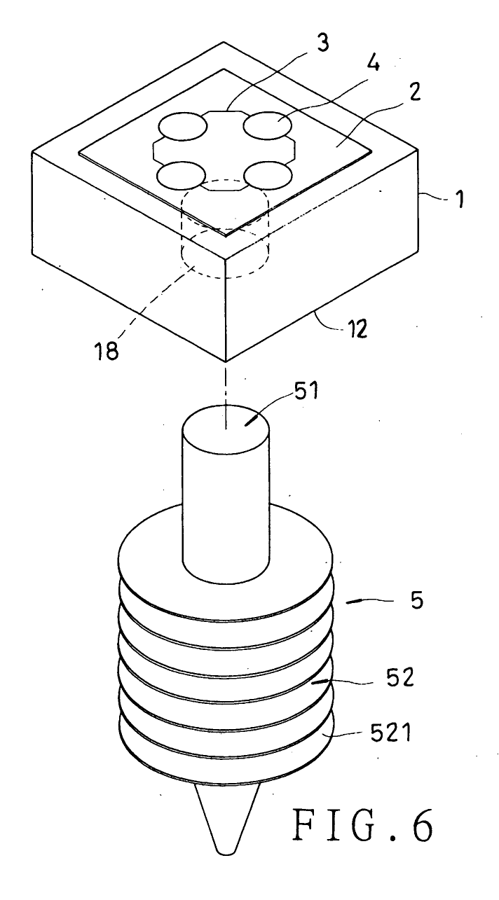

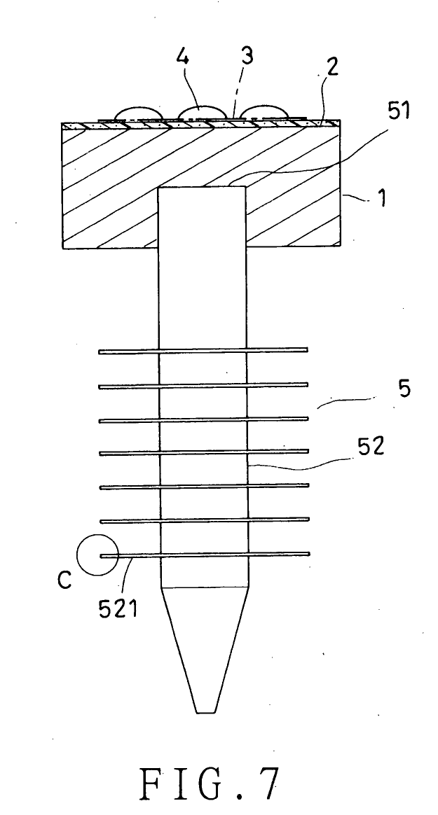

Moreover, the present invention provides a heat sink unit (5) on the heat emitting end (12) of the interface module with high heat-dissipation, as shown in FIGS. 6 and 7. The heat sink unit (5) has a heat absorption end (51) and a heat emitting end (52), and the heat absorption end (51) is detachably combined with the heat emitting end (12) of the metal base (1).

Preferably, the heat sink unit (5) is a thermoelectric cooling chip or a heat pipe.

In the case that the heat sink unit (5) is a heat pipe, a plurality of fins (521) are provided on the heat emitting end (52).

Preferably, each fin (521) is provided with a micro-structure (522), as shown in FIG. 8, which can be one selected from the shape of micro-pit, micro-protrusion, porosity or sponge-like opening, and a heat radiation layer (523) is formed on the surface of the micro-structure (522) by vapor deposition, sputtering, electroplating, sintering or spray-coating. The material of the heat radiation layer (523) is at least one material selected from diamond, aluminum nitride, SiC, diamond-like carbon or nano diamond.

The way of detachable combination between the above mentioned metal base (1) and the heat sink unit (5) is shown in FIGS. 6 and 7, in which the heat sink unit (5) is shown to be a heat pipe. A combination hole (18) is provided on the heat emitting end (12) of the metal base (1), the diameter of which is in conformity with the outside diameter of the heat absorption end (51) of the heat sink unit (heat pipe) (5). Thus, when the heat absorption end (51) of the heat sink unit (heat pipe) (5) is inserted into the combination hole (18), an appropriate press-fit is conducted between them so as to reach steady combination state between the heat sink unit (5) and the metal base (1).

Now the heat conduction mechanism will be explained. The interface module with high heat-dissipation is directly contacted with the electronic components (3) having waste heat generated, at the same time, the interface module with high heat-dissipation is directly contacted with the heat sink unit (heat pipe) (5). In this case, heat sink paste is no longer to be used at the place of mutual contact. Since the interface module with high heat-dissipation itself is a material having good heat conductive efficiency, the waste heat generated by the electronic component (4) having heat generated during operation can be transferred out directly through the electrical insulation layer (2) having high heat-conductivity, the metal base (1) and the heat sink unit (heat pipe) (5) to the ambient air. In this manner, the problem of heat jamming in the low heat-dissipation area is efficiently solved.

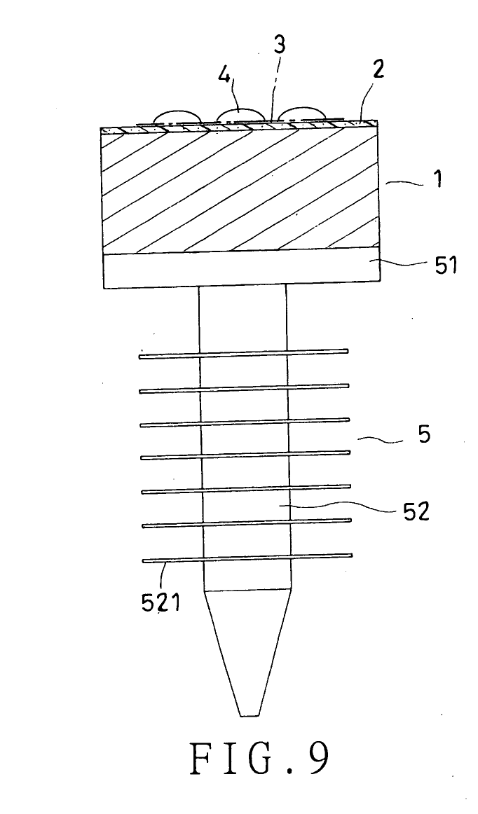

As a matter of course, the way of detachable combination between the above mentioned metal base (1) and the heat sink unit (5) is also shown in FIG. 9, in which the heat absorption end (51) of the heat sink unit (5) is a flat plate type capable of flush with the heat emitting end (12) of the metal base (1). A suitable fixing means (not shown) is used to fasten the heat absorption end (51) of the heat sink unit (5) together with the metal base (1) firmly.

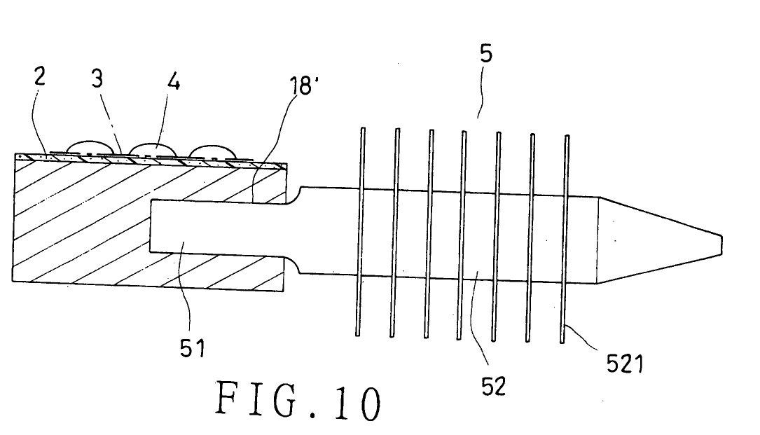

Further referring to FIG. 10, the heat absorption end (51) of the heat sink unit (5) is provided as flat plate type, and a combination hole (18′) having a side opening is provided on the metal base (1) for the horizontal insertion of the heat sink unit (5).

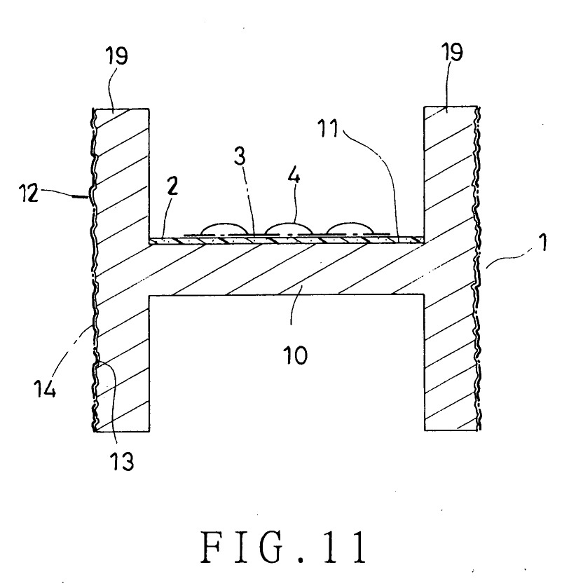

As shown in FIG. 11, the metal base (1) is designed as an H shape having a wall face (19) at both sides thereof and a plate surface (10) connected between the two wall faces (19). On the plate surface (10), the surface for mounting the electronic component (4) is defined as the heat absorption end (11), and the end surface of both wall faces (19) remote from the plate surface is defined as the heat emitting end (12). The surface of the heat emitting end (12) is provided with a micro-structure (13) which can be one selected from the shape of micro-pit, micro-protrusion, porosity or sponge-like opening, and a heat radiation layer (14) is formed on the surface of the micro-structure (13) by vapor deposition, sputtering, electroplating, sintering or spray-coating. The material of the heat radiation layer (14) is at least one material selected from diamond, aluminum nitride, SiC, diamond-like carbon or nano diamond.

What is claimed is:

1. An interface module with high heat-dissipation, wherein it comprises:
a metal base (1) in which the heat absorption end (11) is defined as the end face for mounting the electronic component (4), and the other end face opposite to the heat absorption end (11) is the heat emitting end (12); said metal base (1) is at least one or more than one structure layer without containing any insulation material;
an electrical insulation layer (2) having high heat-conductivity formed on the heat absorption end (11) of the metal base (1); and
a metal circuit (3) formed on the electrical insulation layer (2) with high heat-conductivity.

2. An interface module with high heat-dissipation in accordance with claim 1, wherein said metal base (1) is a single layer structure body the material of which is one material selected from Cu and Al.

3. An interface module with high heat-dissipation in accordance with claim 1, wherein said metal base (1) comprises a first structure layer (1a′) and a second structure layer (1b′), the first structure layer (1a′) being one material selected from Cu and Al, while the second structure layer (1b′) being one material selected from SiC, Si, Mo or Ti.

4. An interface module with high heat-dissipation in accordance with claim 1, wherein said electrical insulation layer (2) with high heat-conductivity is formed on the heat absorption end (11) of the metal base (1) by lamination using a method selected from extrusion, insert welding, stamping, screen printing, spray-coating, remastering or vapor deposition, sputtering, injection, sintering.

5. An interface module with high heat-dissipation in accordance with claim 4, wherein the material of said electrical insulation layer (2) with high heat-conductivity is at least one material selected from diamond, aluminum nitride, SiC, diamond powder mixing with polymer material, diamond-like carbon or nano diamond.

6. An interface module with high heat-dissipation in accordance with claim 1, wherein said metal base (1) of said module is detachably combined with the heat absorption end (51) of a heat sink unit (5) having a heat absorption end (51) and a heat emitting end (52).

7. An interface module with high heat-dissipation in accordance with claim 6, wherein said heat sink unit (5) is a thermoelectric cooling chip.

8. An interface module with high heat-dissipation in accordance with claim 6, wherein said heat sink unit (5) is a heat pipe.

9. An interface module with high heat-dissipation in accordance with claim 8, wherein a plurality of fins (521) are provided on the heat emitting end (51) of said heat pipe.

10. An interface module with high heat-dissipation in accordance with claim 8, wherein the heat emitting end (11) of said metal base (1) has a combination hole (18) for the insertion of the heat absorption end (51) of said heat pipe.

11. An interface module with high heat-dissipation in accordance with claim 8, wherein the heat absorption end (51) of said heat pipe is a flat plate type capable of flush with the heat emitting end (12) of said metal base (1).

12. An interface module with high heat-dissipation in accordance with claim 8, wherein the heat absorption end (51) of said heat pipe is provided as flat plate type, and a combination hole (18′) with a side opening is provided on the metal base (1) for the horizontal insertion of the heat absorption end (51) of said heat pipe.

13. An interface module with high heat-dissipation in accordance with claim 1, wherein at least one electronic component (4) having heat generated is packaged or mounted on said metal base (1).

14. An interface module with high heat-dissipation in accordance with claim 13, wherein said electronic component (4) having heat generated is chip or LED.

15. An interface module with high heat-dissipation in accordance with claim 1, wherein said metal base (1) is formed as a H-shape having wall faces (19) at both sides thereof and a plate surface (10) connected between the two wall faces (19); on the plate surface (10), the surface for mounting the electronic component (4) is defined as the heat absorption end (11), and the end surface of both wall faces (19) remote from the plate surface is defined as the heat emitting end (12).

16. An interface module with high heat-dissipation in accordance with claim 15, wherein the surface of the heat emitting end (12) is provided with a micro-structure (13) which can be one selected from the shape of micro-pit, micro-protrusion, porosity or sponge-like opening.

17. An interface module with high heat-dissipation in accordance with claim 16, wherein a heat radiation layer (14) is formed on the surface of the micro-structure (13) by lamination using a method selected from vapor deposition, sputtering, electroplating, sintering or spray-coating.

18. An interface module with high heat-dissipation in accordance with claim 17, wherein the material of said heat radiation layer (14) is at least one material selected from diamond, aluminum nitride, SiC, diamond-like carbon or nano diamond.

19. An interface module with high heat-dissipation in accordance with claim 1, wherein the surface of the heat emitting end (12) is provided with a micro-structure (13) which can be one selected from the shape of micro-pit, micro-protrusion, porosity or sponge-like opening.

20. An interface module with high heat-dissipation in accordance with claim 19, wherein a heat radiation layer (14) is formed on the surface of the micro-structure (13) by lamination using a method selected from vapor deposition, sputtering, electroplating, sintering or spray-coating, and the material of said heat radiation layer (14) is at least one material selected from diamond, aluminum nitride, SiC, diamond-like carbon or nano diamond.
